(19) United States
(12) Patent Application Publication
(10) Pub. No.: US 2010/0176456 A1
(43) Pub. Date: Jul. 15, 2010

(54) SEMICONDUCTOR DEVICE AND METHOD FOR MANUFACTURING THE SAME

(76) Inventors: Daisuke Ikeno, Yokohama-shi (JP); Kazuaki Nakajima, Tokyo (JP); Toshihiro Iizuka, Kawasaki-shi (JP); Kenzo Manabe, Kawasaki-shi (JP); Ichiro Yamamoto, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/683,050

(22) Filed: Jan. 6, 2010

(30) Foreign Application Priority Data
Jan. 9, 2009 (JP) 2009-003909

(51) Int. Cl. H01L 27/092; H01L 21/8238

(52) U.S. Cl. 257/369; 438/216; 257/E27.062; 257/E21.632

(57) ABSTRACT

A semiconductor device includes a semiconductor substrate including a P-type semiconductor region, and an N channel MOSFET formed in the P-type semiconductor region, the N channel MOSFET including an insulating film of silicon oxide film or silicon oxynitride film formed on the semiconductor substrate, a gate insulating film including hafnium and formed on the insulating film, a lanthanum oxide film having a film thickness not larger than a predetermined value and formed between the gate insulating film and insulating film, and a gate electrode including a titanium nitride film having a N/Ti atomic ratio less than 1.

### CROSS-REFERENCE TO RELATED APPLICATIONS

This application is based upon and claims the benefit of priority from prior Japanese Patent Application No. 2009-003909, filed Jan. 9, 2009, the entire contents of which are incorporated herein by reference.

### BACKGROUND OF THE INVENTION

1. Field of the Invention

The present invention relates to a semiconductor device including a MOSFET having a gate stack structure formed of metal gate electrode/high dielectric constant (high-k) gate insulating film, and to a method for manufacturing the same. In particular, the present invention relates to a semiconductor device including a MOSFET having agate stack structure formed of metal gate electrode containing a titanium nitride film/gate insulating film containing Hf (hafnium), and to a method for manufacturing the same.

2. Description of the Related Art Film thinning of a gate insulating film is required with a scale reduction of large-scale integrated circuits. In complementary metal oxide semiconductors (CMOS) after 32 nm node, a gate insulating film of 0.9 nm or less is required as a SiO₂ conversion film thickness.

On the other hand, conventionally, a polycrystalline silicon gate electrode has been used as a gate electrode. The polycrystalline silicon gate electrode generates depletion resulting from semiconductor characteristics. The depletion of the polycrystalline silicon gate electrode is a factor of increasing the effective film thickness of a gate insulating film, and hindering thinning of the gate insulating film. Therefore, in order to prevent the depletion of the polycrystalline silicon gate electrode, it is desired to employ a metal gate electrode.

The metal gate electrode requires an effective work function (EWF) near to the Si band edge to reduce the threshold voltage (Vₜₕ) of transistors. Specifically, N channel metal oxide semiconductor field effect transistors (NMOSFET) require an EWF near to the Si conduction band edge (4.05 eV). On the other hand, P channel metal oxide semiconductor field effect transistors (NMOSFET) require an EWF near to the Si valence band edge (5.17 eV). The EWF of the Si band edge is realized, and thereby, the foregoing threshold voltage (Vₜₕ) is reduced; as a result, a desired drive force of a CMOS is obtained.

Currently, titanium nitride (TiN) is widely studied as a candidate material of the metal gate electrode in the light of thermal stability and easiness for processing a gate. It is known that the foregoing TiN has an EWF near to the mid-gap of the Si band gap on a high-k insulating film. However, even if the foregoing technique is employed, there is a problem that the reduction of the threshold voltage (Vₜₕ) is not realized.

In view of the foregoing problem, the following technique is employed in an NMOSFET region (see Jpn. Pat. Appln. KOKAI Publication No. 2002-270821). According to the technique, a lanthanum oxide film (cap film) is selectively formed on the interface between TiN electrode/high-k gate insulating film. In this way, a flat band voltage (VFB) is shifted to a negative side, that is, an EWF is reduced, and thereby, the threshold voltage (Vₜₕ) is reduced. Moreover, the following technique is known. Specifically, the shift of the negative side of a flat band voltage (VFB) increases with an increase of the thickness of the lanthanum oxide film, and thereby, the EWF is reduced near Si conduction band edge; in this way, a desired threshold voltage (Vₜₕ) is obtained.

However, if a gate stack structure of TiN electrode/lanthanum oxide film/HfSiON film is used as an NMOSFET, there is the following possibility. Specifically, even if a conventional TiN film whose composition is not controlled is combined with a lanthanum oxide film having a thickness of 1 nm or less, it is difficult to reduce an EWF to the vicinity of the Si conduction band edge. Conversely, if the lanthanum oxide film is formed thicker than 1 nm, it is anticipated that the following problems becomes further serious in a process of selectively removing a lanthanum oxide film on the PMOS side. One is a problem that a lanthanum oxide film locally remains after being removed. Another is a problem that a high dielectric constant (high-k or HfSiON) gate insulating film is reduced. Another is a side etching problem of the foregoing gate insulating film.

### BRIEF SUMMARY OF THE INVENTION

According to an aspect of the present invention, there is provided a semiconductor device comprising: a semiconductor substrate including a P-type semiconductor region; and an N channel MOSFET formed in the P-type semiconductor region, the N channel MOSFET comprising an insulating film of silicon oxide film or silicon oxynitride film formed on the semiconductor substrate, a gate insulating film including hafnium and formed on the insulating film, a lanthanum oxide film having a film thickness not larger than a predetermined value and formed between the gate insulating film and insulating film, and a gate electrode including a titanium nitride film having a N/Ti atomic ratio less than 1.

According to an aspect of the present invention, there is provided a method for manufacturing a semiconductor device comprising: forming an insulating film of silicon oxide film or silicon oxynitride film on a semiconductor substrate including an N-type semiconductor region and a P-type semiconductor region; forming a gate insulating film including hafnium on the insulating film; forming a lanthanum oxide film having a film thickness not larger than a predetermined value selectively on the gate insulating film, thereafter selectively removing the lanthanum oxide film above the N-type semiconductor region; forming a gate electrode including a titanium nitride film having a N/Ti atomic ratio less than 1 on the lanthanum oxide film of the P-type semiconductor region and on the gate insulating film of the N-type semiconductor region; and forming a lanthanum oxide film having a film thickness not larger than a predetermined value between the insulating film and the gate insulating film by heat treatment for diffusing lanthanum oxide constituting the lanthanum oxide film between the insulating film and the gate insulating film.

### BRIEF DESCRIPTION OF THE SEVERAL VIEWS OF THE DRAWING

FIG. 1 is a cross-sectional view to explain a method for manufacturing a semiconductor device according to a first embodiment;

FIG. 2 is a cross-sectional view following FIG. 1 to explain a method for manufacturing a semiconductor device according to a first embodiment;

FIG. 3 is a cross-sectional view following FIG. 2 to explain a method for manufacturing a semiconductor device according to a first embodiment;

FIG. 4 is a cross-sectional view following FIG. 3 to explain a method for manufacturing a semiconductor device according to a first embodiment;

FIG. 5 is a cross-sectional view following FIG. 4 to explain a method for manufacturing a semiconductor device according to a first embodiment;

FIG. 6 is a cross-sectional view following FIG. 5 to explain a method for manufacturing a semiconductor device according to a first embodiment;

FIG. 7 is a cross-sectional view following FIG. 6 to explain a method for manufacturing a semiconductor device according to a first embodiment;

FIG. 8 is a graph showing dependency of shift amount of VFB to a negative side by addition of LaₓO_{y} films on N/Ti atomic ratio of TiN film at the time of forming in a case of MOS capacitor having a poly-Si/TiN/LaₓO_{y}/HfSiON/SiO₂/Si stack structure;

FIG. 9 is a graph showing dependency of Tacc on N/Ti atomic ratio of TiN film at the time of forming in a case of MOS capacitor having a poly-Si/TiN/LaₓO_{y}/HfSiON/SiO₂/Si stack structure;

FIG. 10 is a cross-sectional view to explain a semiconductor device according to a second embodiment;

FIG. 11 is a graph showing dependency of VFB on N/Ti atomic ratio of TiN film at the time of forming in a case of MOS capacitor having a poly-Si/TiN/LaₓO_{y}/HfSiON/SiO₂/Si stack structure;

FIG. 12 is a cross-sectional view to explain a method for manufacturing a semiconductor device according to a second embodiment;

FIG. 13 is a cross-sectional view following FIG. 12 to explain a method for manufacturing a semiconductor device according to a second embodiment;

FIG. 14 is a cross-sectional view following FIG. 13 to explain a method for manufacturing a semiconductor device according to a second embodiment; and

FIG. 15 is a cross-sectional view to explain a semiconductor device according to a third embodiment.

### DETAILED DESCRIPTION OF THE INVENTION

Hereinafter, embodiments of the present invention will be described with reference to the drawings.

### First Embodiment

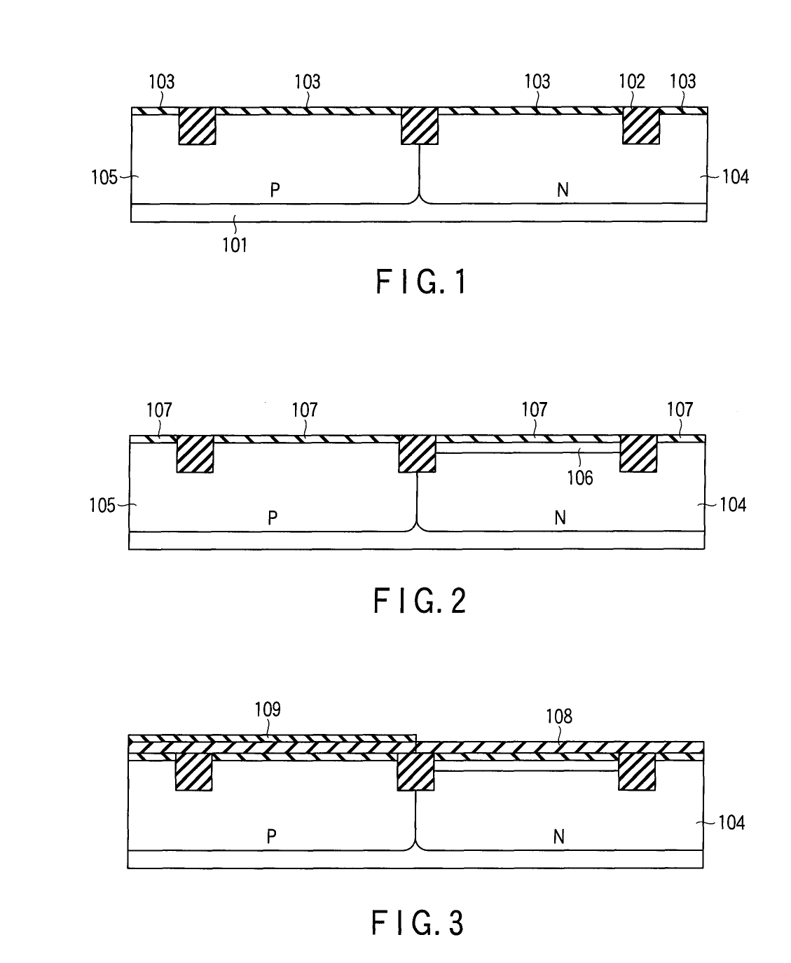

FIGS. 1 to 7 are cross-sectional views to explain a method for manufacturing a semiconductor device according to a first embodiment, and show cross-sectional views in a channel length direction of a MOSFET.

[FIG. 1]

A silicon substrate 101 is formed with an isolation region 102 having a shallow trench isolation (STI) structure, a sacrificial oxide film 103, an N-type diffusion layer (N-type semiconductor region) 104 and a P-type diffusion layer (P-type semiconductor region) 105 according to a known method.

[FIG. 2]

The sacrificial oxide film on the N-type diffusion layer 104 is removed by means of a NH₄F solution or diluted hydrofluoric acid using a resist (not shown) covering the P-type diffusion layer 105 as a mask. In this way, SiGe is selectively and epitaxially grown on the N-type diffusion layer 104 to form a channel SiGe layer 106. Further, a Si film (not shown) is formed on the channel SiGe layer 106. The foregoing resist (not shown) is removed, and then, the sacrificial oxide film on the P-type diffusion layer 105 is removed using a NH₄F solution or diluted hydrofluoric acid. Thereafter, a chemical SiO₂ film (silicon oxide film) 107 is formed on both of N- and P-type diffusion layers 104 and 105.

Here, the chemical SiO₂ film (silicon oxide film) 107 is formed as the interface layer, a silicon oxynitride film (SiON film) may be formed in place of the chemical SiO₂ film. The method for forming the silicon oxynitride film includes the following processes. For example, one is a process of forming a chemical SiO₂ film. Another is a process of nitrifying (e.g., plasma-nitrifying) the chemical SiO₂ film. Another is a process of oxidizing (e.g., oxygen-anneal oxidizing) the nitrified chemical SiO₂ film.

[FIG. 3]

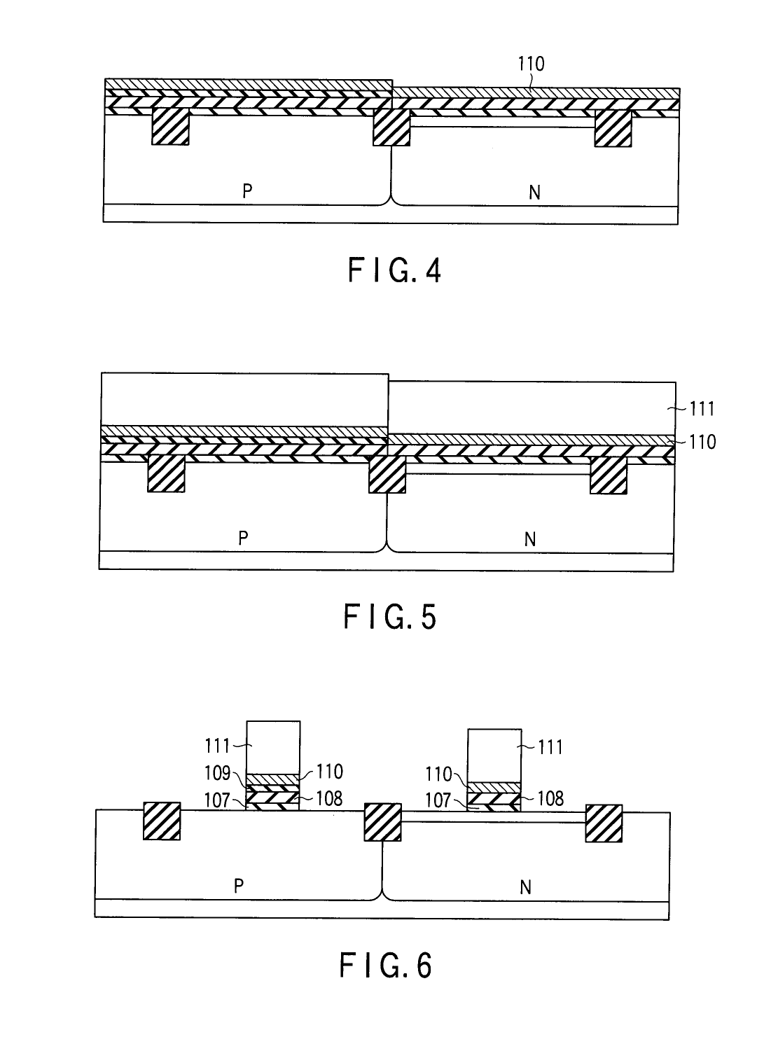

A HfSiO film (hafnium silicon oxide film) (not shown) is formed on the entire surface using a MOCVD process. The foregoing HfSiO film (not shown) is treated in a nitrogen plasma atmosphere, and thereafter, heat treatment is carried out so that the HfSiO film (not shown) is modified to a HfSiON (hafnium silicon nitride film) 108. Further, a lanthanum oxide film having a thickness of 1 nm or less is deposited on the entire surface using a PVD process. Then, the lanthanum oxide film on the N-type diffusion layer 104 is removed by etching using a resist (not shown) as a mask. In this way, a lanthanum oxide film 109 given as a cap layer is selectively formed on the P-type diffusion layer 105. Thereafter, the foregoing resist (not shown) is removed.

[FIG. 4]

A TiN (titanium nitride) film 110 is formed on the entire surface using a Ti target reactive sputtering process. At this time, an N₂/Ar flow rate in forming a film is controlled to form a TiN film 110 having a N/Ti atomic ratio ranging from 0.67 or more to 1.00 or less. In place of the foregoing sputtering process, the N/Ti atomic ratio may be controlled using a CVD process and an ALD process to form the TiN film 110.

[FIG. 5]

A Si film 111 is formed on the TiN film 110.

[FIG. 6]

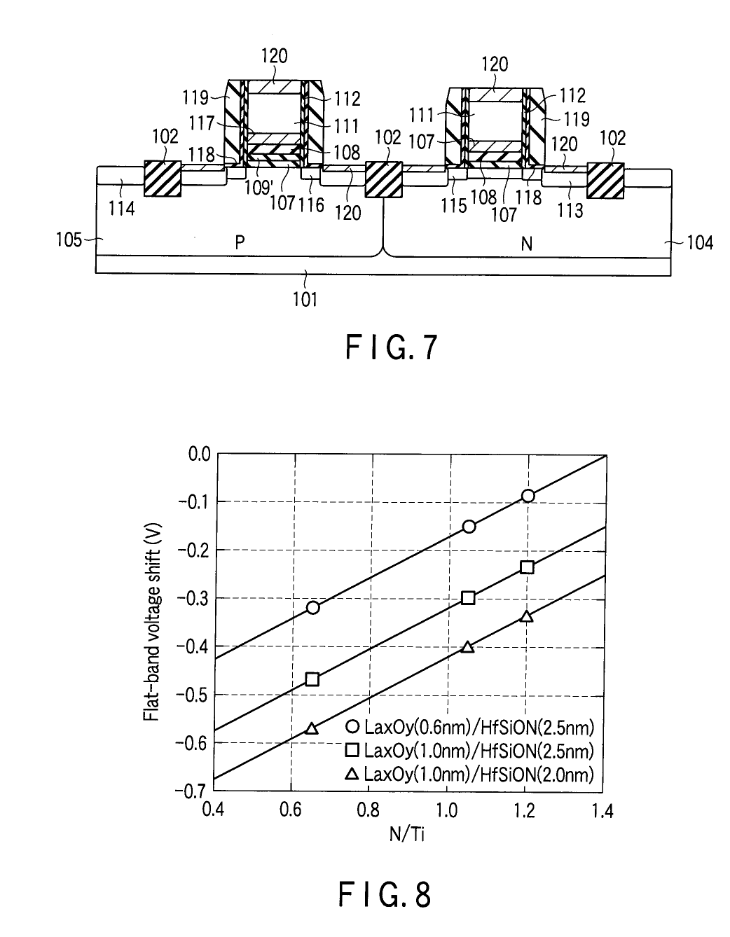

The foregoing Si film 111 and TiN film 110 are etched by means of RIE using a hard mask (not shown). Further, the HfSiON film 108 and the SiO₂ film 107 are etched in the N-type diffusion region while the lanthanum oxide film 109, the HfSiON film 108 and the SiO₂ film 107 are etched in the P-type diffusion region.

[FIG. 7]

An insulating film such as a silicon oxide film or a silicon nitride film is deposited on a surface including regions where gate electrodes (of N and P channel MOSFETs in the diffusion layers 104 and 105.) are to be formed, by means of a CVD process. The deposited insulating film is etched using RIE, and thereby, an offset spacer 112 is formed. Further, a sidewall spacer (not shown) formed of a silicon oxide film or a silicon nitride film is formed by means of a CVD process and RIE.

B ions are implanted into the N-type diffusion layer 104 using a resist (not shown) as a mask. Likewise, P or As ions are implanted into the P-type diffusion layer 105 using a resist (not shown) as a mask. Thereafter, heat treatment is carried out, and thereby, a p-type source/drain diffusion layer 113 and an N-type source/drain diffusion layer 114 are formed.

The foregoing sidewall spacer (not shown) is removed, and thereafter, B ions are implanted into the N-type diffusion layer 104 using a resist (not show) as a mask. Likewise, P or As ions are implanted into the P-type diffusion layer 105 using a resist (not shown) as a mask. Thereafter, heat treatment is carried out, and thereby, a P-type extension diffusion layer 115 and an N-type extension diffusion layer 116 are formed.

In this case, nitrogen of the TiN film 110 diffuses in the HfSiON film (high-k gate insulating film) 108 by heat treatment in forming the foregoing diffusion layers 115 and 116. Finally, a TiN electrode (metal gate electrode) 117 having a N/Ti atomic ratio of 1 or less is formed.

Further, a lanthanum oxide of the lanthanum oxide film 109 formed in the process of FIG. 3 diffuses between the silicon oxide film 107 and the HfSiON film 108 by the foregoing heat treatment. Finally, a lanthanum oxide film 109′ having a thickness of a predetermined value or less is formed between the foregoing films 107 and 108. The thickness of the lanthanum oxide film 109′ is less than that of the lanthanum oxide film 109.

The foregoing heat treatment to form the lanthanum oxide film 109′ is not specially limited so long as heat treatment is carried out after the lanthanum oxide film 109 is formed. Moreover, optimized heat treatment may be independently carried out for the purpose of forming the lanthanum oxide film 109′.

A two-layer sidewall spacer formed of a SiO₂ film 118 and a silicon nitride film 119 is formed using a CVD process and RIE. A silicide film 120 is formed on the surface of source/drain diffusion layers 113, 114 and a Si film 11 by means of a known self-align salicide process. As a result, the NMOS side is formed with gate electrodes 120, 111 and 109 having a silicide/Si/metal gate stack structure.

Thereafter, the following processes carried out in a conventional transistor; specifically, an interlayer insulating film is formed, a contact hole is opened and filled, and interconnects are formed. In this way, it is possible to form a semiconductor integrated circuit including a CMOSFET.

FIG. 8 is a graph showing dependency of shift amount of flat band voltage (VFB) to a negative side (VFB negative shift amount) by addition of 0.6 nm and 1.0 nm LaₓO_{y} films on N/Ti atomic ratio of TiN film 110 at the time of forming in a case of MOS capacitor having a poly-Si/TiN/LaₓO_{y}/HfSiON/SiO₂/Si stack structure;

As can be seen from FIG. 8, there is a tendency that the negative shift amount of VFB by addition of LaₓO_{y} with the same thickness (corresponding to lanthanum oxide film 109) increases as the N/Ti atomic ratio of TiN (corresponding to TiN film 110) decreases. The reason results from the following matters.

When the N/Ti atomic ratio is decreased, amount of nitrogen diffusing from TiN to HfSiON (corresponds to HfSiON film 108) is decreased. The reduction of amount of nitrogen is generated by heat treatment. The heat treatment in the present embodiment is, for example, the heat treatment for forming the diffusion layers 115 and 116 of the device in the present embodiment.

Here, nitrogen of HfSiON hinders the diffusion of La (lanthanum) in HfSiON. Therefore, the N/Ti atomic ratio is decreased, amount of the nitrogen diffusing into HfSiON is decreased, and thereby the amount of La of HfSiON is increased, and the amount of La at the interface between HfSiON/SiO₂ is increased. The foregoing La forms a dipole (La interface dipole) at the interface between HfSiON/SiO₂ interface. The La interface dipole contributes for increasing the negative shift of a flat-band voltage (VFB). Therefore, the reason of increasing of negative shift amount of VFB due to the reduction of N/Ti atomic ratio is considered that the La interface dipole is increased by the reduction of N/Ti atomic ratio.

Further, as can be seen from FIG. 8, the negative shift amount of VFB depends on thickness of the LaₓO_{y} film and the HfSiON film. It is seen that the TiN film 110 having a N/Ti atomic ratio of 1 or less is good enough to realize 300 mV or more (performance required as a device) of negative shift amount of VFB when the thickness of the HfSiON film is in a range of 2.0-2.5 nm and the thickness of the LaₓO_{y} film is 1.0 nm or less.

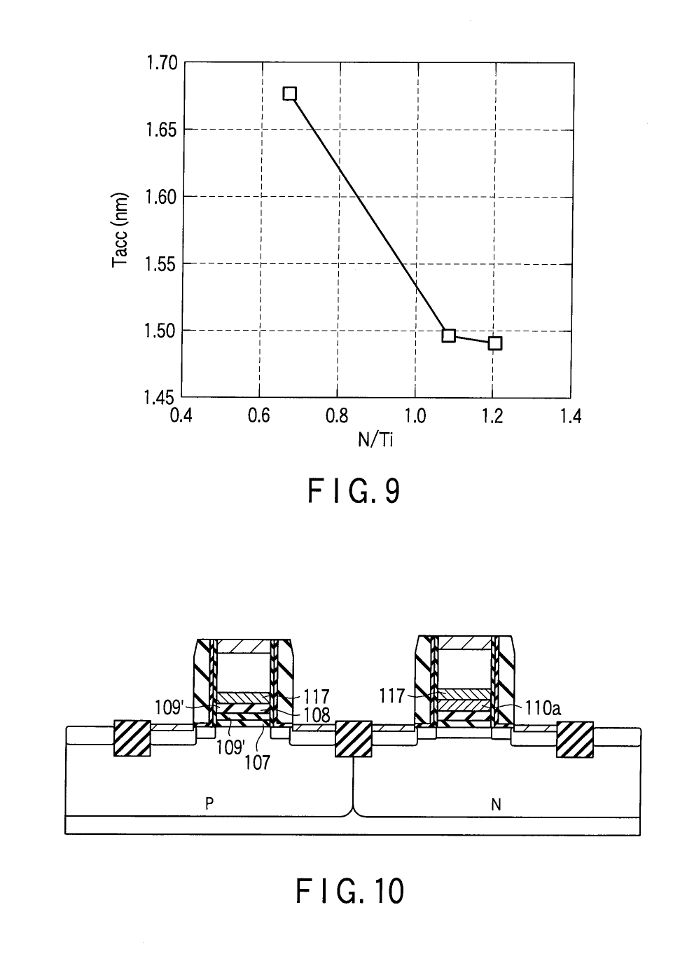

FIG. 9 is a graph showing dependency of accumulated capacitance conversion thickness (Tacc) on N/Ti atomic ratio of TiN film at the time of forming in a case of MOS capacitor having a poly-Si/TiN/LaₓO_{y}/HfSiON/SiO₂/Si stack structure. As can be seen from FIG. 9, there is a tendency for the Tacc to increase with a decrease of the N/Ti atomic ratio. This is because the N/ti atomic ratio decreases, and thereby, the thermal stability of TiN is reduced. Therefore, considering the thermal stability of a TiN film, a TiN film 110 having a N/Ti atomic ratio ranging from 0.67 to 1.00 is formed, and thereby, the effect is sufficiently obtained. The foregoing N/Ti atomic ratio of the TiN film 110 can be confirmed by means of measurement using a Rutherford backscattering method (RBS).

According to the present embodiment, the composition of TiN is intentionally controlled so that the N/Ti atomic ratio is set to 1 or less. If the composition of TiN is not intentionally controlled, the N/Ti atomic ratio falls into 1, which is a thermally stable N/Ti atomic ratio, and the problem under subject matter is not solved.

### Second Embodiment

FIG. 10 is a cross-sectional view to explain a semiconductor device according to a second embodiment. In the drawings after FIG. 10, the portions corresponding to the portions shown in the previously mentioned drawings are denoted by the same reference numerals and omitted its detail explanation. In addition, even if portions corresponding to previously mentioned drawings exist, the reference numerals are not used in the case where the reference numerals are unnecessary for explanation or no misunderstanding is given.

According to the first embodiment, a TiN film having a N/Ti atomic ratio ranging from 0.67 or more to 1 or less is formed on both of NMOS and PMOS sides.

On the contrary, according to this present embodiment, a TiN film 110a having a N/Ti atomic ration larger than 1 is further selectively formed on the PMOS side. A TiN film 117 having the same N/Ti atomic ratio as the first embodiment is formed on the TiN film 110a.

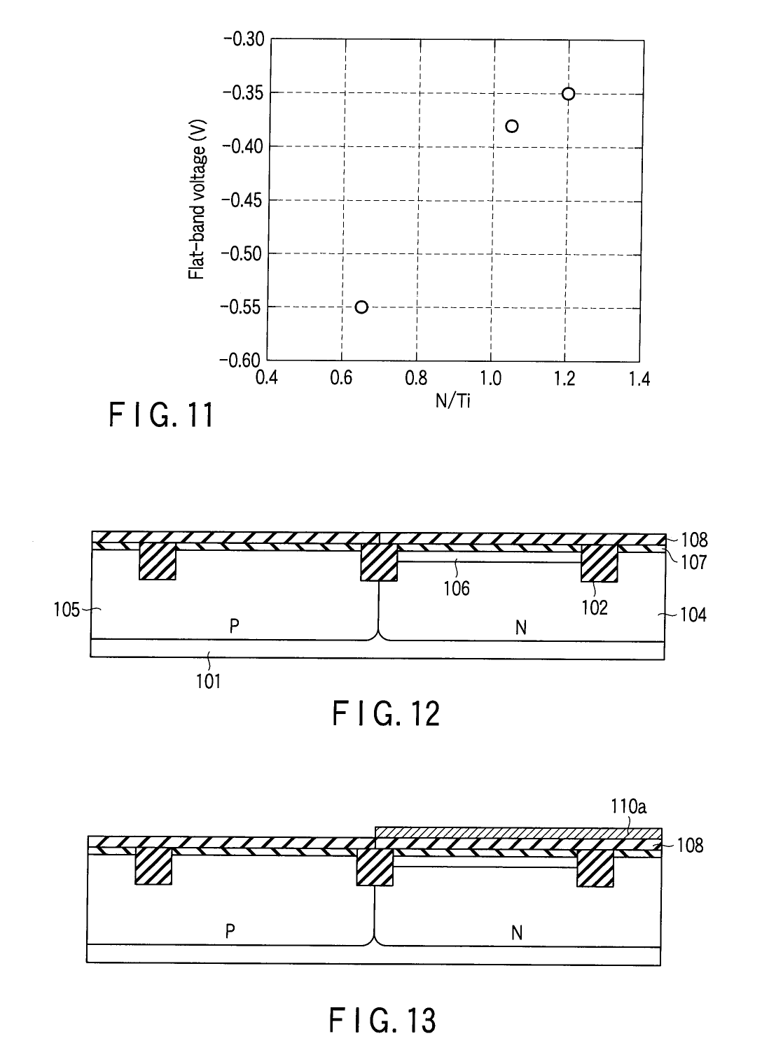

The following is an explanation of the reason why the N/Ti atomic ratio of the TiN film on the PMOS side is set to 1 or more. FIG. 11 is a graph showing dependency of VFB on N/Ti atomic ratio of TiN film at the time of forming in a case of MOS capacitor having a poly-Si/TiN/LaₓO_{y}/HfSiON/SiO₂/Si stack structure. As can be seen from FIG. 11, there is a tendency for the VFB to shift to a negative side with a decrease of the N/Ti atomic ratio. Thus, according to the present embodiment, a TiN film having a N/Ti atomic ratio of 1 or more is formed in order to make high VFB on the PMOS side as possible as can.

FIGS. 12 to 14 are cross-sectional views to explain a method for manufacturing the semiconductor device according to the second embodiment.

[FIG. 12]

A silicon substrate 101 is formed with an isolation region 102, an N-type diffusion layer 104, a P-type diffusion layer 105, a channel SiGe layer 106 and a HfSiON film 108, like the first embodiment.

[FIG. 13]

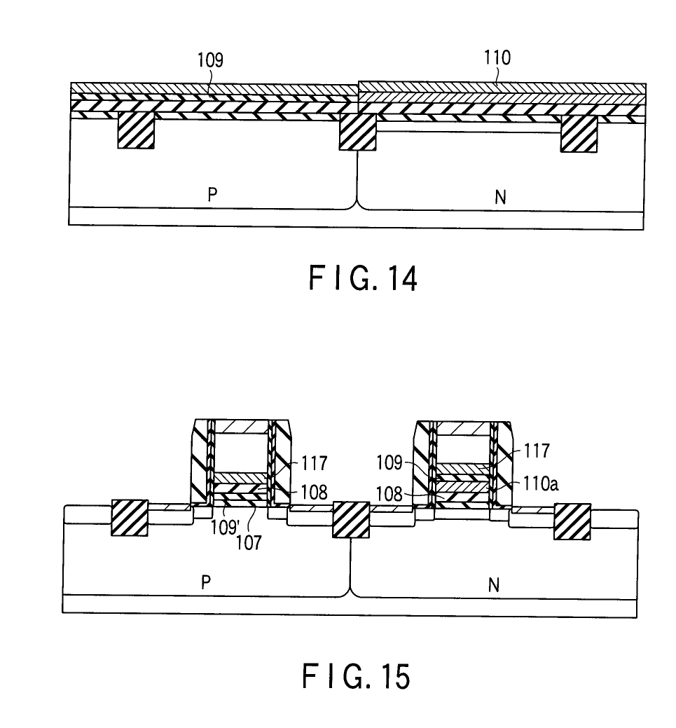

A TiN film having a N/Ti atomic ratio of 1 or more is formed on the HfSiON film 108. Then, a TiN film on the NMOS side is etched using a resist (not shown) as a mask. In this way, a TiN film 110a (first titanium nitride film) having a N/Ti atomic ratio of 1 or more is selectively left on the HfSiON film 108 on the PMOS side.

[FIG. 14]

A lanthanum oxide film is formed on the entire surface by means of a PVD process. Then, a lanthanum oxide film on the PMOS side is etched using a resist (not shown) as a mask. In this way, a lanthanum oxide film 109 is selectively left on the HfSiON 108 on the NMOS side. A TiN film 110 (second titanium nitride film) having a N/Ti atomic ratio ranging from 0.67 or more to 1 or less is formed on the entire surface (lanthanum oxide film 109 on the NMOS side, TiN film 110a on the PMOS side).

Thereafter, a semiconductor device shown in FIG. 10 is obtained via the same processes (after the process of FIG. 5) as the first embodiment.

### Third Embodiment

FIG. 15 is a cross-sectional view showing a semiconductor device according to a third embodiment.

According to the second embodiment, a lanthanum oxide film exists on the NMOS side, but it does not exist on the PMOS side.

On the contrary, according to the present embodiment, a lanthanum oxide film 109 exists on both NMOS and PMOS sides. This serves to prevent a threshold voltage variation in the PMOS side, which is caused by etching residue of La oxide. The La residue has higher influence on the threshold voltage than the TiN residue.

The structure of the present embodiment, i.e., the structure in which the lanthanum oxide film further exists on the PMOS side (TiN/La/TiN) is obtained by a process which comprises selectively removing the TiN film on the NMOS side, then forming a lanthanum oxide film, thereafter, forming a TiN film on both MMOS and PMOS sides again.

In addition, in the present embodiment, even if the lanthanum oxide film is left on the PMOS side, the TiN film 110a is interposed between the lanthanum oxide film 109 and the HfSiON film 108. The TiN film 110a prevents La (lanthanum) of the lanthanum oxide film 109 from diffusing into the HfSiON film 108. Therefore, there is no need to consider the flat-band voltage (VFB) shift by La diffusion from the lanthanum oxide film 109 left on the PMOS side to the HfSiON film 108.

The present invention is not limited to the foregoing embodiments.

For example, according to the foregoing embodiments, after forming the source/drain diffusion layer, the sidewall spacer is removed to form the extension diffusion layer, but the extension diffusion layer may be formed after an offset spacer is formed, and thereafter, the source/drain diffusion layer may be formed after the sidewall spacer is formed.

The foregoing embodiments show the case where the present invention is applied to a CMOS (N and P channel MOSFET), but the present invention may be applied to an N channel MOSFET only.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate including a P-type semiconductor region; and
an N channel MOSFET formed in the P-type semiconductor region, the N channel MOSFET comprising an insulating film of silicon oxide film or silicon oxynitride film formed on the semiconductor substrate, a gate insulating film including hafnium and formed on the insulating film, a lanthanum oxide film having a film thickness not larger than a predetermined value and formed between the gate insulating film and insulating film, and a gate electrode including a titanium nitride film having a N/Ti atomic ratio less than 1.

2. The semiconductor device according to claim 1, wherein the predetermined value is 1 nm.

3. The semiconductor device according to claim 1, wherein the semiconductor substrate further includes an N-type semiconductor region, a P channel MOSFET is formed in the N-type semiconductor region, the P channel MOSFET comprises a gate insulating film including hafnium and a gate electrode including a titanium nitride film having a N/Ti atomic ratio less than 1.

4. The semiconductor device according to claim 3, wherein the gate electrode of the P channel MOSFET further includes a titanium nitride film having a N/Ti atomic ratio not less than 1, the titanium nitride film having the N/Ti atomic ratio not less than 1 is selectively provide under the titanium nitride film having the N/Ti atomic ratio less than 1

5. The semiconductor device according to claim 1, wherein the N/Ti atomic ratio is not less than 0.67.

6. The semiconductor device according to claim 3, wherein the N channel MOSFET and the P channel MOSFET constitute a CMOS.

7. The semiconductor device according to claim 3, wherein both the N/Ti atomic ratios of titanium nitride films of the N and P channel MOSFETs are not less than 0.67.

8. The semiconductor device according to claim 3, wherein the P channel MOSFET further comprises a lanthanum oxide film.

9. The semiconductor device according to claim 8, wherein the lanthanum oxide film is provided between the titanium nitride film and the gate insulating film of the P channel MOSFET.

10. A method for manufacturing a semiconductor device comprising:
forming an insulating film of silicon oxide film or silicon oxynitride film on a semiconductor substrate including an N-type semiconductor region and a P-type semiconductor region;
forming a gate insulating film including hafnium on the insulating film;
forming a lanthanum oxide film having a film thickness not larger than a predetermined value selectively on the gate insulating film, thereafter selectively removing the lanthanum oxide film above the N-type semiconductor region;
forming a gate electrode including a titanium nitride film having a N/Ti atomic ratio less than 1 on the lanthanum oxide film of the P-type semiconductor region and on the gate insulating film of the N-type semiconductor region; and
forming a lanthanum oxide film having a film thickness not larger than a predetermined value between the insulating film and the gate insulating film by heat treatment for diffusing lanthanum oxide constituting the lanthanum oxide film between the insulating film and the gate insulating film.

11. The method for manufacturing the semiconductor device according to claim 10,
further comprising forming extensions of the N channel MOSFET and P channel MOSFET, and wherein heat treatment for forming the extensions serves the heat treatment for diffusing the lanthanum oxide.

12. The method for manufacturing the semiconductor device according to claim 10,
further comprising forming a titanium nitride film having a N/Ti atomic ratio not less than 1 selectively on the N-type semiconductor region before forming the titanium nitride film having the N/Ti atomic ratio less than 1.

13. The method for manufacturing the semiconductor device according to claim 10,
further comprising forming a gate insulating film including hafnium before forming the titanium nitride film having the N/Ti atomic ratio less than 1, forming a hafnium silicon oxide film on the gate insulating film, and treating the hafnium silicon oxide film in nitrogen plasma atmosphere.

14. The method for manufacturing the semiconductor device according to claim 13,
further comprising modifying the hafnium silicon oxide film treated in the nitrogen plasma atmosphere by heating.
